(19) United States
(12) Patent Application Publication
(10) Pub. No.: US 2018/0067581 A1
(43) Pub. Date: Mar. 8, 2018

(54) CONDUCTIVE STRUCTURE AND MANUFACTURING METHOD THEREFOR

(71) Applicant: LG CHEM, LTD., Seoul (KR)

(72) Inventors: Ilha LEE, Daejeon (KR); Ki-Hwan KIM, Daejeon (KR); Song Ho JANG, Daejeon (KR); Jin Woo PARK, Daejeon (KR); Chan Hyoung PARK, Daejeon (KR)

(73) Assignee: LG CHEM, LTD., Seoul (KR)

(21) Appl. No.: 15/558,064

(22) PCT Filed: Mar. 25, 2016
(86) PCT No.: PCT/KR2016/003076

§ 371 Date: Sep. 13, 2017

(30) Foreign Application Priority Data
Mar. 25, 2015 (KR) 10-2015-0041786

(51) Int. Cl. G06F 3/044; H05K 1/02; H05K 3/46; H05K 3/06; G06F 3/041

(52) U.S. Cl. CPC G06F 3/044; H05K 1/028; H05K 1/0274; H05K 3/46; G06F 2203/04112; G06F 3/0412; H05K 2201/0104; G06F 2203/04103; H05K 3/06

(57) ABSTRACT

The present specification relates to a conductive structure body and a manufacturing method thereof.

### TECHNICAL FIELD

The present specification relates to a conductive structure body and a manufacturing method thereof.

This application claims priority to and the benefit of Korean Patent Application No. 10-2015-0041786 filed in the Korean Intellectual Property Office on Mar. 25, 2015, the entire contents of which are incorporated herein by reference.

### BACKGROUND ART

In general, touch screen panels may be classified as follows according to a signal detection type. That is, there are a resistive type that detects a position pressed by pressure through a change in a current or voltage value while DC voltage is applied, a capacitive type using capacitance coupling while AC voltage is applied, an electromagnetic type that detects a selected position as a change in voltage while a magnetic field is applied, and the like.

A commercialized touch screen panel is used based on an ITO thin film, but when a large-area touch screen panel is applied, there is a disadvantage in that a touch recognition speed is lowered due to the surface resistance of an ITO transparent electrode itself. Accordingly, as a technology for replacing the transparent ITO thin film, a metal mesh used for an electrode of the touch screen panel is proposed. However, in the case of the metal mesh, efforts for improving problems such as a visibility problem in which a pattern is visible well to the human eye due to a high reflection and glare due to a high reflection for external light are required.

Korean Patent Publication No. 10-2010-0007605.

### DETAILED DESCRIPTION OF THE INVENTION

### Technical Problem

The present specification has been made in an effort to provide a conductive structure body which may be applied to a large-area touch screen panel, may maintain excellent visibility, and has excellent product reliability due to low connection resistance of a pad portion, and a manufacturing method thereof.

### Technical Solution

An exemplary embodiment of the present specification provides a conductive structure body including a substrate; and a conductive line configuring a screen portion, a wiring portion, and a pad portion provided on the substrate, in which the conductive line includes a metal layer, a first light reflection reducing layer provided on the metal layer, and a second first light reflection reducing layer provided on the first light reflection reducing layer, the first light reflection reducing layer and the second light reflection reducing layer contain aluminum oxynitrides, and the element content of nitrogen atoms of the second light reflection reducing layer is smaller than the element content of nitrogen atoms of the first light reflection reducing layer.

Another exemplary embodiment of the present specification provides a manufacturing method of the conductive structure body, the manufacturing method including: preparing a substrate; forming a metal layer on the substrate; forming a first light reflection reducing layer on the metal layer; forming a second light reflection reducing layer on the first light reflection reducing layer; and patterning of forming a conductive line configuring a screen portion, a wiring portion, and a pad portion by patterning the metal layer, the first light reflection reducing layer, and the second light reflection reducing layer.

Still another exemplary embodiment of the present specification provides a touch panel including the conductive structure body.

Yet another exemplary embodiment of the present specification provides a display device including the touch panel.

### Advantageous Effects

According to the exemplary embodiment of the present specification, the conductive structure body has advantages of maintaining excellent electric conductivity and efficiently preventing a glare effect of a metal layer. Further, the conductive structure body according to the exemplary embodiment of the present specification has advantages of having excellent visibility and excellent chemical durability and physical durability.

Further, the conductive structure body according to the exemplary embodiment of the present specification has advantages of minimizing a drop in electric conductivity of the conductive structure body according to a process environment in the case of being applied to an electronic device such as a display device.

Further, the conductive structure body according to the exemplary embodiment of the present specification may improve visibility by implementing a fine line width of a conductive line configuring a screen portion.

Further, the conductive structure body according to the exemplary embodiment of the present specification may largely reduce connection resistance between a flexible printed circuit board (FPCB) and a conductive line.

### BRIEF DESCRIPTION OF DRAWINGS

FIG. 1 illustrates a placement structure of a conductive line in a conductive structure body according to an exemplary embodiment of the present specification.

FIG. 2 illustrates a laminated structure of a conductive line configuring a screen portion in the conductive structure body according to the exemplary embodiment of the present specification.

FIG. 3 illustrates light reflections of conductive structure bodies according to Examples.

FIG. 4 illustrates light reflections of conductive structure bodies according to Comparative Examples.

### EXPLANATION OF REFERENCE NUMERALS AND SYMBOLS

100: Substrate
200: Metal layer
310: First light reflection reducing layer
320: Second light reflection reducing layer
410: Conductive line configuring screen portion
420: Conductive line configuring wiring portion
430: Conductive line configuring pad portion

### BEST MODE

In this specification, it will be understood that when a member is referred to as being “on” another member, it can be directly on the other member or intervening members may also be present.

Throughout the specification, unless explicitly described to the contrary, the word “comprise” and variations such as “comprises” or “comprising” will be understood to imply the inclusion of stated elements but not the exclusion of any other elements.

“Conductivity” of the present specification means electric conductivity.

Further, in the present specification, a “reflection” means a light reflection, a “refractive index” means a light refractive index”, and an absorbance means a light absorbance.

The present inventors found problems that when a light reflection reducing layer is formed to prevent a glare effect of a metal mesh for replacing an ITO film, the light reflection reducing layer is provided on a conductive line configuring a pad portion connected with a flexible printed circuit board (FPCB), and as a result, connection resistance with the FPCB is increased and further, deterioration of performance of the pad portion is caused in a high-temperature and high-humidity environment.

Therefore, the present inventors developed a conductive structure body according to an exemplary embodiment of the present specification. Specifically, the conductive structure body according to the exemplary embodiment of the present specification may improve performance of the pad portion and minimize a defect of the pad portion by lowering connection resistance of the conductive line configuring the pad portion as well as reducing a glare effect of a conductive line configuring a screen portion.

Hereinafter, the present specification will be described in more detail.

An exemplary embodiment of the present specification provides a conductive structure body including: a substrate; and a conductive line configuring a screen portion, a wiring portion, and a pad portion provided on the substrate, in which the conductive line includes a metal layer, a first light reflection reducing layer provided on the metal layer, and a second first light reflection reducing layer provided on the first light reflection reducing layer, the first light reflection reducing layer and the second light reflection reducing layer contain aluminum oxynitrides, and the element content of nitrogen atoms of the second light reflection reducing layer is smaller than the element content of nitrogen atoms of the first light reflection reducing layer.

In the conductive structure body according to the exemplary embodiment of the present specification, the first light reflection reducing layer serves to reduce a glare effect of the metal layer. Specifically, since the first light reflection reducing layer includes aluminum oxynitride having a high element content of nitrogen atoms to have a feature that a light reflection is significantly low, the glare effect caused by the metal layer provided below the first light reflection reducing layer may be suppressed.

However, in the case of the first light reflection reducing layer, there is a problem in that connection resistance of the pad portion is high due to low electric conductivity. In order to improve the problem, in a conductive laminate according to an exemplary embodiment of the present specification, the second light reflection reducing layer is provided on the first light reflection reducing layer to lower the connection resistance of the pad portion. Specifically, since the second light reflection reducing layer includes aluminum oxynitride having a low element content of nitrogen atoms and has high electrical conductivity, the second light reflection reducing layer may contribute to lowering the connection resistance of the pad portion.

The second light reflection reducing layer has a higher light reflection than the first light reflection reducing layer, but when the second light reflection reducing layer is laminated with the first light reflection reducing layer together, the light reflection of the conductive line has visibility enough to have no glare effect.

Since the first light reflection reducing layer and the second light reflection reducing layer are provided on the metal layer as thin films, each of the light reflection reducing layers may be in a semi-transparent state. The light reflection reducing layers are laminated on the metal layer, respectively, to adjust a light characteristic and electric conductivity of the conductive line.

According to the exemplary embodiment of the present specification, the second light reflection reducing layer may include aluminum oxynitride in which a value of Equation 1 below satisfies 0.5 or more and 0.7 or less.

$$\frac{{N}_{at \%}}{{Al}_{at \%} - \frac{2}{3} {O}_{at \%}} \qquad [ Equation 1 ]$$

In Equation 1, N_{at %} means the elemental content of nitrogen atoms with respect to the aluminum oxynitride, Al_{at %} means the elemental content of aluminum atoms with respect to the aluminum oxynitride, and O_{at %} means the elemental content of oxygen atoms with respect to the aluminum oxynitride.

Equation 1 means the element content of nitrogen with respect to the element content of aluminum which is not coupled with oxygen in the aluminum oxynitride. The present inventors found that in the aluminum oxynitride of the light reflection reducing layer, a light reflection reducing characteristic and a resistance characteristic are determined according to the content of nitrogen. Further, the present inventors found that when the second light reflection reducing layer including aluminum oxynitride that satisfies the value of Equation 1 of 0.5 to 0.7 is provided on the first light reflection reducing layer having a relatively high resistance, a defect rate of the pad portion may be decreased by sufficiently lowering the connection resistance of the conductive line configuring the pad portion, while ensuring visibility of the conductive line configuring the screen portion.

Specifically, according to the exemplary embodiment of the present specification, the value of Equation 1 may be 0.6 or more and 0.7 or less.

According to the exemplary embodiment of the present specification, the first light reflection reducing layer may include aluminum oxynitride in which a value of Equation 2 below satisfies 1 or more and 2 or less.

$$\frac{3 {Al}_{at \%}}{2 {O}_{at \%} + 3 {N}_{at \%}} \qquad [ Equation 2 ]$$

In Equation 2, N_{at %} means the elemental content of nitrogen atoms with respect to the aluminum oxynitride, Al_{at %} means the elemental content of aluminum atoms with respect to the aluminum oxynitride, and O_{at %} means the elemental content of oxygen atoms with respect to the aluminum oxynitride.

When the value of Equation 2 is larger than 1, an absorption coefficient is increased to form the first light reflection reducing layer that may sufficiently prevent the glare effect of the lower metal layer. Further, when the value obtained in Equation 2 is larger than 2, the content of Al is further increased to form a metallic layer and thus, it is difficult to prevent the glare effect of the lower metal layer.

The element content included in the prepared layer may be measured through an X-ray photo electron spectroscopy (XPS). This is a measuring method that may find a composition and a chemical binding state of a sample by measuring energy of photoelectrons emitted by inputting X rays to the surface of the sample.

According to the exemplary embodiment of the present specification, a thickness of the second light reflection reducing layer may be 5 nm or more and 60 nm or less. Specifically, according to the exemplary embodiment of the present specification, the thickness of the second light reflection reducing layer may be 10 nm or more and 60 nm or less.

When the thickness of the second light reflection reducing layer satisfies the range, an increase in light reflection due to the second light reflection reducing layer is minimized, and simultaneously, the connection resistance of the conductive structure body may be sufficiently lowered. When the thickness of the second light reflection reducing layer is more than 60 nm, there may be a problem in that the glare effect caused by the second light reflection reducing layer is increased and thus visibility is deteriorated.

According to the exemplary embodiment of the present specification, a thickness of the first light reflection reducing layer may be 10 nm or more and 100 nm or less. Specifically, according to the exemplary embodiment of the present specification, the thickness of the first light reflection reducing layer may be 20 nm or more and 60 nm or less. More specifically, according to the exemplary embodiment of the present specification, the thickness of the first light reflection reducing layer may be 30 nm or more and 60 nm or less.

When the thickness of the first light reflection reducing layer is less than 10 nm, there may be a problem in that physical and chemical damages to the metal layer are not sufficiently prevented. Further, when the thickness of the first light reflection reducing layer is more than 100 nm, there may be a problem in that it is difficult to pattern the first light reflection reducing layer.

According to the exemplary embodiment of the present specification, a specific resistance of the second light reflection reducing layer may be 10⁻4 Ωcm or more and 5×10⁻³ Ωcm or less.

The specific resistance may be obtained by measuring a surface resistance of the deposited film and then multiplying a thickness by the measured surface resistance according to the following Equation.

Specific resistance (Rs)=surface resistance (ρ)/thickness (t)

Alternatively, the specific resistance may be directly measured through a hall measurement method. The second light reflection reducing layer has a low specific resistance value to largely lower the connection resistance of the conductive line configuring the pad portion and thus reduce a defect ratio of the pad portion when bonding a flexible printed circuit board (FPCB). Particularly, the connection resistance of the pad portion is calculated as Equation below.

Connection resistance (Rc)=contact specific resistance (ρc)/contact area (Ac)

Therefore, the connection resistance of the conductive line configuring the pad portion may be determined by a specific resistance of the second light reflection reducing layer and a contact area of the light reflection reducing layer and a flexible printed circuit board (FPCB) or an anisotropic conductive film (ACF). Therefore, the light reflection reducing layer may embody a lower connection resistance even under the same contact area.

According to the exemplary embodiment of the present specification, an extinction coefficient k of the conductive line may be 1.2 or more and 2.2 or less in light having a wavelength of 633 nm.

When the extinction coefficient is in the range, concealment of the metal layer is improved and visibility may be further improved when the conductive structure body is applied to a touch screen panel. Further, when the extinction coefficient k of the conductive line is in the range, both the visibility of the conductive line configuring the screen portion and the low connection resistance of the conductive line configuring the pad portion may be satisfied.

The extinction coefficient may be measured by using an ellipsometer measuring instrument and the like which are known in the art.

The extinction coefficient k is also called an absorption coefficient and is an element of determining transmittance of the conductive structure body, as a measure capable of defining how strong the conductive structure body absorbs light in a predetermined wavelength. For example, in the case of a transparent dielectric material, k<0.2, and a k value is very small. However, as a metal component is increased in the material, the k value is increased. If the metal component is further increased, the material becomes a metal in which transmittance hardly occurs and only surface reflection mostly occurs, and the extinction coefficient k is more than 2.5 and thus, it is not preferred in the formation of the light reflection reducing layer.

According to the exemplary embodiment of the present specification, a refractive index n of the conductive line may be 2 or more and 2.4 or less in the light having a wavelength of 600 nm.

According to the exemplary embodiment of the present specification, the thickness of each light reflection reducing layer may be determined depending on a refractive index with reference to Equation 1.

$$d = \frac{λ}{4 n} N ( N = 1 , 3 , 5 , … ) \qquad [ Equation 1 ]$$

In Equation 1, d is a thickness of the light reflection reducing layer, n is a refractive index, and λ is a wavelength of light.

According to the exemplary embodiment of the present specification, the total reflection means a reflection to light at a wavelength area of 300 to 800 nm and particularly 380 to 780 nm, which is incident at 90° to the surface to be measured after an opposite surface to the surface to be measured is treated with perfect black. In the present specification, the total reflection is a value measured based on light at a wavelength area of 300 or more and 800 nm or less and particularly 380 or more and 780 nm or less of reflection light reflected by a target pattern layer or a conductive structure body to which the light is incident when incident light is 100%.

The reflection may be measured in an opposite direction to a surface of the light reflection reducing layer contacting the metal layer when the metal layer is provided between the substrate and the light reflection reducing layer. Particularly, when the light reflection reducing layer includes a first surface contacting the metal layer and a second surface facing the first surface, the reflection may be measured in a direction of the second surface.

According to the exemplary embodiment of the present specification, the metal layer may be a metal pattern layer and the light reflection reducing layer may be a light reflection reducing pattern layer. In this case, when the total reflection of the conductive structure body is measured at the second surface side of the light reflection reducing pattern layer, a total reflection Rt of the conductive structure body may be calculated by Equation 2 below.

Total reflection Rt=reflection of substrate+closure rate×reflection of light reflection reducing layer [Equation 2]

Further, when the configuration of the conductive structure body is a case where two types of conductive structure bodies are laminated, the total reflection Rt of the conductive structure body may be calculated by Equation 3 below.

Total reflection Rt=reflection of substrate+closure rate×reflection of light reflection reducing layer×2 [Equation 3]

In Equations 2 and 3, the total reflection of the substrate may be a reflection of touch tempered glass and when the surface is a film, the total reflection may be the reflection of the film. Further, the closure rate may be represented by an area ratio, that is, (1—aperture ratio) occupied by a region covered by the conductive pattern based on the plane of the conductive structure body.

According to the exemplary embodiment of the present specification, the total reflection of the conductive structure body may be 40% or less. Particularly, according to the exemplary embodiment of the present specification, the total reflection of the screen portion in the light in a wavelength range of 380 nm to 780 nm may be 40% or less.

In the present specification, the screen portion may mean an area corresponding to a display screen when the conductive structure body is applied to a display device. When the conductive structure body is used as a touch panel, the conductive line configuring the screen portion may serve to transfer an electric signal to the conductive line of the wiring portion by sensing a touch.

In the present specification, the wiring portion may mean an area corresponding to a bezel area of the display device when the conductive structure body is applied to a display device. When the conductive structure body is used as the touch panel, the conductive line configuring the wiring portion may serve to transfer the electric signal transferred from the conductive line of the screen portion to the conductive line configuring the pad portion.

In the present specification, the pad portion may mean an area contacting a flexible printed circuit board (FPCB). When the conductive structure body is used as the touch panel, the conductive line configuring the pad portion may serve to transfer the electric signal transferred from the wiring portion to the FPCB. Further, the pad portion may be a FPCB bonding pad portion.

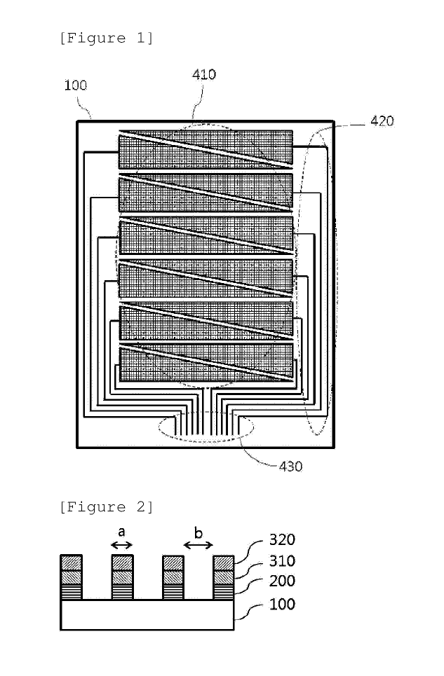

FIG. 1 illustrates a placement structure of a conductive line in a conductive structure body according to an exemplary embodiment of the present specification. In FIG. 1, the conductive line configuring the screen portion is provided to have a mesh pattern, the conductive line configuring the wiring portion is provided as a structure which is extended to the conductive line configuring the pad portion by using the bezel region, and the conductive line configuring the pad portion may form a set of ends of the conductive line. However, the conductive line of the conductive structure body according to the exemplary embodiment of the present specification is not limited to the structure of FIG. 1 and may be embodied by various structures.

According to the exemplary embodiment of the present specification, a flexible printed circuit board (FPCB) may be further included on the conductive line configuring the pad portion.

According to the exemplary embodiment of the present specification, an anisotropic conductive film (ACF) may be further included between the conductive line configuring the pad portion and the FPCB. Particularly, the conductive line configuring the pad portion and the FPCB may be electrically connected to each other through the ACF.

The FPCB has a bending characteristic and means a board in which when circuits between components of an electronic product are connected with each other, a circuit is drawn on the board without using wires to conduct electricity. The FPCB of the present specification may be applied without limitation as long as the FPCB is generally used in the art.

The ACF is a film in which conductive particles are dispersed, and means a film having electric conductivity in a z axis and showing insulation in a z-y plane direction. The ACF of the present specification may be applied without limitation as long as the ACF is generally used in the art.

According to the exemplary embodiment of the present specification, the FPCB may be provided to be more adjacent to the second light reflection reducing layer than the first light reflection reducing layer. Particularly, according to the exemplary embodiment of the present specification, the ACF is provided on the second light reflection reducing layer and the FPCB may be provided on the ACF.

According to the exemplary embodiment of the present specification, the screen portion may include a plurality of apertures and a conductive pattern including the conductive line partitioning the apertures.

According to the exemplary embodiment of the present specification, the conductive line configuring the screen portion may form a regular pattern or an irregular pattern. In detail, the conductive line configuring the screen portion may be provided by forming a pattern on the transparent substrate through a patterning process.

Particularly, the pattern may have a polygon such as a triangle and a quadrangle, a circle, an ellipse, or an amorphous shape. The triangle may be a regular triangle, a right-angled triangle, or the like and the quadrangle may be a square, a rectangle, a trapezoid, or the like.

As the regular pattern, a pattern form in the art such as a mesh pattern may be used. The irregular pattern is not particularly limited, but may be a boundary line form of figures configuring a Voronoi diagram. According to the exemplary embodiment of the present application, in the case of using the irregular pattern as the pattern form, a diffractive pattern of reflective light by oriented lighting may be removed by the irregular pattern and an effect by scattering of light may be minimized by the light reflection reducing pattern layer, and as a result, the problem in the visibility may be minimized.

According to the exemplary embodiment of the present specification, a line width of the conductive line configuring the screen portion may be 0.1 μm or more and 100 μm or less. Particularly, according to the exemplary embodiment of the present specification, a line width of the conductive line configuring the screen portion may be 0.1 μm or more and 50 μm or less, 0.1 μm or more and 30 μm or less, or 0.1 μm or more and 10 μm or less, but is not limited thereto. The line width of the conductive line configuring the screen portion may be designed according to a final use of the conductive structure body.

When the line width of the conductive line configuring the screen portion is less than 0.1 μm, it is difficult to embody the pattern, and when the line width is more than 100 μm, the visibility may be deteriorated.

Each light reflection reducing layer may have a pattern having the same shape as the metal layer. However, a pattern scale of each light reflection reducing layer needs not to be completely the same as that of the metal layer, and even a case where the line width of the pattern in each light reflection reducing layer is smaller than or larger than the line width of the pattern in the metal layer is included in the range of the present specification. Particularly, the line width of the pattern in each light reflection reducing layer may be 80% or more and 120% or less of the line width of the pattern in the metal layer. Further, an area provided with the pattern in each light reflection reducing layer may be 80% or more and 120% or less of an area provided with the pattern in the metal layer. More particularly, the pattern form of each light reflection reducing layer may be a pattern form having a line width which is equal to or larger than the line width of the pattern in the metal layer.

When each light reflection reducing layer has a pattern shape having a line width which is larger than the line width of the metal layer, when viewed from the user, each light reflection reducing layer may largely give an effect of covering the metal layer, and thus, there is an advantage in that an effect by luster or reflection of the metal layer itself may be efficiently blocked. However, even though the line width of the pattern in each light reflection reducing layer is the same as the line width of the pattern in the metal layer, an effect of reducing the light reflection may be achieved.

According to the exemplary embodiment of the present specification, a line gap between adjacent conductive lines in the conductive line configuring the screen portion may be 0.1 μm or more and 100 μm or less.

According to the exemplary embodiment of the present specification, the line gap may be 0.1 μm or more, more particularly 10 μm or more, and much more particularly 20 μm or more. Further, according to the exemplary embodiment of the present specification, the line gap may be 100 μm or less and more particularly 30 μm or less.

According to the exemplary embodiment of the present specification, since the metal layer and each light reflection reducing layer may be embodied by patterns having fine line widths, in the case of being used as an electrode of the touch panel of the display element, there is an advantage in that visibility is excellent.

FIG. 2 illustrates a laminated structure of a conductive line of a screen portion in the conductive structure body according to the exemplary embodiment of the present specification. In FIG. 2, it is illustrated that a substrate, a patterned metal layer, a patterned first light reflection reducing layer, and a patterned second light reflection reducing layer are sequentially provided. However, the conductive structure body is not limited to the structure of FIG. 2, but additional layers may be further included.

In FIG. 2, a means a line width of the conductive line, and b means a line gap between adjacent conductive lines.

According to the exemplary embodiment of the present specification, the metal layer may include one or more selected from the group consisting of at least one metal of copper, aluminum, silver, neodymium, molybdenum, nickel and chromium, alloys including at least two of the metals, oxides including at least one of the metals, and nitrides including at least one of the metals. In detail, according to the exemplary embodiment of the present specification, the metal layer may include aluminum. According to the exemplary embodiment of the present specification, the metal layer may be made of aluminum. Further, according to the exemplary embodiment of the present specification, the metal layer may include aluminum as a main component. However, due to a manufacturing process, some of impurities may be included.

According to the exemplary embodiment of the present specification, a thickness of the metal layer may be 10 nm or more and 1 μm or less. Particularly, according to the exemplary embodiment of the present specification, the thickness of the metal layer may be 100 nm or more and more particularly 150 nm or more. Further, according to the exemplary embodiment of the present specification, the thickness of the metal layer may be 500 nm or less and more particularly 200 nm or less. Since the electric conductivity depends on a thickness, if the metal layer is very thin, a continuous thickness is not formed and thus there may be a problem in that a specific resistance value is increased, and as a result, the thickness of the metal layer may be 100 nm or more.

According to the exemplary embodiment of the present specification, an additional metal layer may be further included between the transparent conductive layer and the metal layer.

According to the exemplary embodiment of the present specification, the additional metal layer may include two or more metals selected from a group consisting of copper, aluminum, neodymium, molybdenum, titanium, nickel and chromium. In detail, the additional metal layer may include Cu—Ni.

The additional metal layer may serve to minimize deterioration of electrical conductivity of the conductive structure body and improve adhesion between the transparent conductive layer and the metal layer.

According to the exemplary embodiment of the present specification, the substrate is not particularly limited and may use a material which is known in the art. According to the exemplary embodiment of the present specification, the transparent substrate may use any transparent substrate, for example, may be glass, polyethylene terephthalate (PET), polycarbonate (PC) or polyamide (PA).

According to the exemplary embodiment of the present specification, a transparent conductive layer may be further provided between the transparent substrate and the metal layer.

According to an exemplary embodiment of the present specification, a transparent conductive oxide layer may be used as the transparent conductive layer. The transparent conductive oxide may use indium oxide, zinc oxide, indium tin oxide, indium zinc oxide, indium zinc tin oxide, an amorphous transparent conductive polymer, etc., and use one kind or two kinds or more thereof, but is not limited thereto. According to the exemplary embodiment of the present specification, the transparent conductive layer may be an indium tin oxide layer.

According to the exemplary embodiment of the present specification, a thickness of the transparent conductive layer may be 15 nm or more and 20 nm or less, but is not limited thereto. The transparent conductive layer may be formed by using the aforementioned material for the transparent conductive layer through a deposition process or a printing process.

An exemplary embodiment of the present specification provides a manufacturing method of the conductive structure body.

An exemplary embodiment of the present specification provides a manufacturing method of the conductive structure body, the manufacturing method including: preparing a substrate; forming a metal layer on the substrate; forming a first light reflection reducing layer on the metal layer; forming a second light reflection reducing layer on the first light reflection reducing layer; and patterning of forming a conductive line configuring a screen portion, a wiring portion, and a pad portion by patterning the metal layer, the first light reflection reducing layer, and the second light reflection reducing layer.

According to the exemplary embodiment of the present specification, in the forming of the metal layer, the metal layer may be formed on one surface of the substrate as an entire layer.

According to the exemplary embodiment of the present specification, in the forming of the first light reflection reducing layer, the first light reflection reducing layer may be formed on one surface of the metal layer as an entire layer.

According to the exemplary embodiment of the present specification, in the forming of the second light reflection reducing layer, the second light reflection reducing layer may be formed on one surface of the first light reflection reducing layer as an entire layer.

The entire layer may mean one physically continuous side or film which is formed on an area of 80% or more of one surface of a lower member formed with a target member. Particularly, the entire layer may mean one layer before being patterned.

According to the exemplary embodiment of the present specification, the forming of the metal layer, the forming of the first light reflection reducing layer, and the forming of the second light reflection reducing layer may use methods such as deposition, sputtering, wet coating, evaporation, electroplating or electroless plating, lamination of a metal film, and the like. Particularly, according to the exemplary embodiment of the present specification, the forming of the metal layer, the forming of the first light reflection reducing layer, and the forming of the second light reflection reducing layer may use a deposition or sputtering method, respectively.

Further, according to the exemplary embodiment of the present specification, the forming of the metal layer, the forming of the first light reflection reducing layer, and the forming of the second light reflection reducing layer may use a printing method, respectively. In the case of forming the metal layer, the first light reflection reducing layer, and the second light reflection reducing layer by the printing method, ink or paste including a metal may be used, and the paste may further include a binder resin, a solvent, a glass frit, and the like in addition to the metal.

According to the exemplary embodiment of the present specification, in the patterning, the metal layer, the first light reflection reducing layer, and the second light reflection reducing layer may be simultaneously patterned.

According to the exemplary embodiment of the present specification, the patterning may use a material having an etching resist characteristic. The etching resist may form a resist pattern by using a printing method, a photolithography method, a photography method, a dry film resist method, a wet resist method, a method using a mask or laser transfer, for example, thermal transfer imaging, and the like, and particularly, a dry film resist method may be used. However, the etching resist is not limited thereto. The metal layer, the first light reflection reducing layer, and the second light reflection reducing layer are etched and patterned by using the etching resist pattern and the etching resist pattern may be easily removed by a strip process.

According to the exemplary embodiment of the present specification, in the patterning, the metal layer, the first light reflection reducing layer, and the second light reflection reducing layer may be batch-etched by using the etchant.

In the manufacturing method according to the exemplary embodiment of the present specification, when the metal layer, the first light reflection reducing layer, and the second light reflection reducing layer include the same kind of metal, since the metal layer, the first light reflection reducing layer, and the second light reflection reducing layer may be etched using the same etchant, there is an advantage in that the metal layer and each of the light reflection reduction layers can be batch-etched. Particularly, according to the exemplary embodiment of the present specification, the metal layer, the first light reflection reducing layer, and the second light reflection reducing layer include Al, respectively, and the etchant may be an Al etchant, and etchants which are generally used in the art may be used without limitation.

An exemplary embodiment of the present specification provides a touch panel including the conductive structure body. The touch panel includes the same meaning as a touch screen panel. For example, in a capacitive touch panel, the conductive structure body according to the exemplary embodiment of the present specification may be used as a touch sensitive electrode substrate.

Further, an exemplary embodiment of the present specification provides a display device including the touch panel.

In this specification, a display device collectively refers to a TV, a computer monitor, or the like and includes a display element forming images and a case supporting the display element.

The touch screen panel including according to the exemplary embodiment of the present specification may further include an additional structure body other than the aforementioned conductive structure body. In this case, two structure bodies may be disposed in the same direction, or may be disposed in directions opposite to each other. Two or more structure bodies that may be included in the touch screen panel need not to have the same structure, and any one, preferably, only the structure body closest to the user may include the aforementioned conductive structure body, and an additional structure body may not include the light reflection reducing layer. Further, layer-laminated structures in the two or more structure bodies may be different from each other. When two or more structure bodies are included, an insulating layer may be provided therebetween. In this case, the insulating layer may additionally have a function as an adhesive layer.

The touch screen panel according to the exemplary embodiment of the present specification may include a lower substrate; an upper substrate; and an electrode layer provided on any one surface or two surfaces of a surface of the lower substrate contacting the upper substrate and a surface of the upper substrate contacting the lower substrate. The electrode layers may perform a function for detecting an X-axial position and a Y-axial position, respectively.

In this case, one or both of the electrode layer provided on the lower substrate and the surface of the lower substrate contacting the upper substrate; and the electrode layer provided on the upper substrate and the surface of the upper substrate contacting the lower substrate may be the conductive structure body according to the aforementioned exemplary embodiment of the present specification. In the case where only one of the electrode layers is the conductive structure body according to the exemplary embodiment of the present specification, the other electrode layer may have a conductive pattern which is known in the art.

In the case where the electrode layers are provided on one-side surfaces of both the upper substrate and the lower substrate to form an electrode layer of two layers, an insulating layer or a spacer may be provided between the lower substrate and the upper substrate so that a distance between the electrode layers is uniformly maintained and the electrode layers are not connected to each other. The insulating layer may include an adhesive or a UV or thermosetting resin. The touch screen panel may further include a ground portion connected to the pattern of the conductive layer of the aforementioned conductive structure body. For example, the ground portion may be formed at an edge of the surface with the pattern of the conductive layer of the substrate. Further, at least one of an anti-reflective film, a polarization film, and an anti-fingerprinting film may be provided on at least one surface of a laminate including the conductive structure body. According to a design specification, different kinds of functional films may further be included in addition to the aforementioned functional films. As described above, the touch screen panel may be applied to display devices such as an OLED display panel, a liquid crystal display (LCD), a cathode-ray tube (CRT), and a PDP.

In the touch screen panel according to the exemplary embodiment of the present specification, the conductive pattern layer and the light reflection reducing layer may be provided on two surfaces of the substrate, respectively.

The touch screen panel according to the exemplary embodiment of the present specification may additionally include an electrode portion or a pad portion on the conductive structure body. In this case, an effective screen portion, the electrode portion, and the pad portion may be configured by the same conductive body.

In the touch screen panel according to the exemplary embodiment of the present specification, the light reflection reducing layer may be provided at a side viewed by the user.

An exemplary embodiment of the present specification provides a display device including the conductive structure body. In the display device, the conductive structure body according to the exemplary embodiment of the present application may be used in a color filter substrate, a thin film transistor substrate, or the like.

An exemplary embodiment of the present specification provides a solar cell including the conductive structure body. For example, the solar cell may include an anode electrode, a cathode electrode, a photoactive layer, a hole transporting layer and/or an electron transporting layer, and the conductive structure body according to the exemplary embodiment of the present application may be used as the anode electrode and/or the cathode electrode.

The conductive structure body may replace conventional ITO in the display device or the solar cell and may be used as a flexible application. Further, the conductive structure body may be used as a next-generation transparent electrode together with CNT, a conductive polymer, graphene, or the like.

Hereinafter, the present specification will be described in detail with reference to Examples for a specific description. However, the Examples according to the present specification may be modified in various forms, and it is not interpreted that the scope of the present invention is limited to the Examples described in detail below. The Examples of the present specification will be provided for more completely explaining the present invention to those skilled in the art.

### Examples and Comparative Examples

In order to manufacture a metal layer, a first light reflection reducing layer, and a second light reflection reducing layer, in Examples, deposition was performed by using a sputtering method. Thereafter, light refractive indexes and absorption coefficients of the first light reflection reducing layer and the second light reflection reducing layer were measured using an ellipsometer. By using the measured light refractive indexes and absorption coefficients, a reflection for a wavelength of 400 nm to 700 nm at a thickness as shown in Table 1 was confirmed using a light reflection simulation program.

Further, in the case of Comparative Examples, the light reflection simulation was performed in the same manner as in the above Example, except that the second light reflection reducing layer was not formed.

TABLE 1

| | | Thickness of | Thickness of |
|---|---|---|---|
| | Thickness | first light | second light |
| | of metal | reflection | reflection |
| | layer | reducing layer | reducing layer |
| | (nm) | (nm) | (nm) |
| Example 1 | 100 | 30 | 30 |
| Example 2 | 100 | 40 | 30 |
| Example 3 | 100 | 35 | 35 |
| Example 4 | 100 | 30 | 35 |
| Example 5 | 100 | 30 | 25 |
| Comparative | 100 | 30 | — |
| Example 1 | | | |
| Comparative | 100 | 60 | — |
| Example 2 | | | |

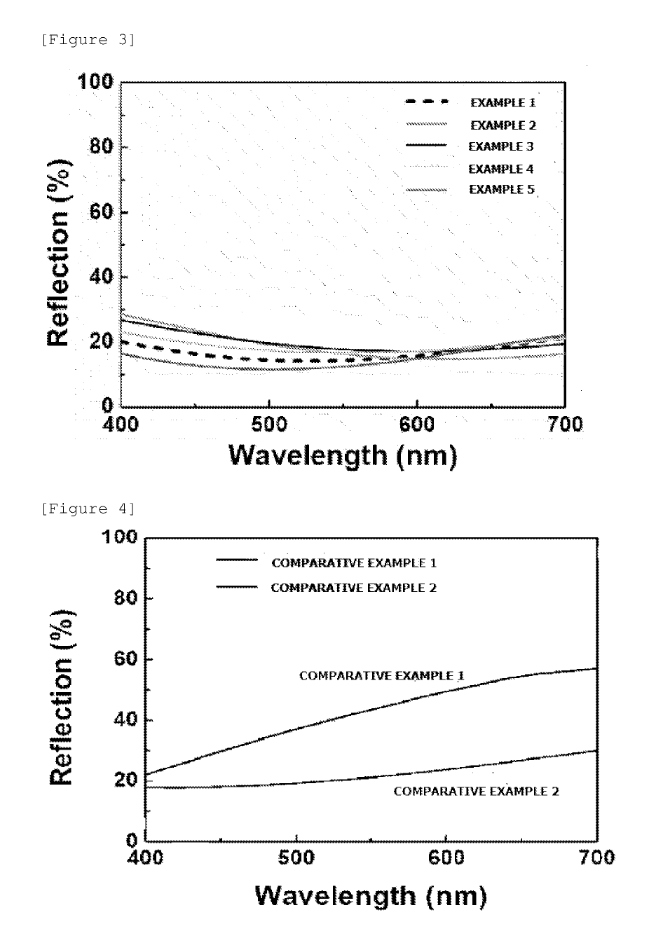

Light reflections of the conductive structure bodies according to Examples with thicknesses illustrated in Table 1 were illustrated in FIG. 3. Light reflections of the conductive structure bodies according to Comparative Examples with thicknesses illustrated in Table 1 were illustrated in FIG. 4.

According to FIGS. 3 and 4, it can be seen that the light reflections of the conductive structure bodies manufactured according to Examples is lower than the light reflections of the conductive structure bodies according to Comparative Examples in the whole wavelength range.

In the conductive structure body, the connection resistance at the time of bonding may be determined by a specific resistance value of the outermost light reflection reducing layer contacting the FPCB. Therefore, it may be deduced that the conductive structure bodies according to Examples has excellent connection resistance in bonding compared to the conductive structure bodies according to Comparative Examples by the second light reflection reducing layer having excellent conductivity.

Specifically, when in Examples and Comparative Examples, the light reflection reducing layers having the same thickness are provided, the connection resistance of the conductive laminate according to Examples having the second light reflection reducing layer is further lowered. Further, the conductive structure body according to Examples exhibits a stably low reflection as compared with Comparative Examples, and thus excellent visibility in the screen portion as well as the low connection resistance may be deduced.

1. A conductive structure body comprising:
a substrate; and
a conductive line configuring a screen portion, a wiring portion, and a pad portion provided on the substrate,
wherein the conductive line includes a metal layer, a first light reflection reducing layer provided on the metal layer, and a second light reflection reducing layer provided on the first light reflection reducing layer,
the first light reflection reducing layer and the second light reflection reducing layer include aluminum oxynitrides, and
the element content of nitrogen atoms of the second light reflection reducing layer is smaller than the element content of nitrogen atoms of the first light reflection reducing layer.

2. The conductive structure body of claim 1, wherein the second light reflection reducing layer includes aluminum oxynitride in which a value of Equation 1 below satisfies 0.5 or more and 0.7 or less:
$$\frac{{N}_{at \%}}{{Al}_{at \%} - \frac{2}{3} {O}_{at \%}} \qquad [ Equation 1 ]$$
In Equation 1, N_{at %} means the elemental content of nitrogen atoms with respect to the aluminum oxynitride, Al_{at %} means the elemental content of aluminum atoms with respect to the aluminum oxynitride, and O_{at %} means the elemental content of oxygen atoms with respect to the aluminum oxynitride.

3. The conductive structure body of claim 1, wherein the first light reflection reducing layer includes aluminum oxynitride in which a value of Equation 2 below satisfies 1 or more and 2 or less:
$$\frac{3 {Al}_{at \%}}{2 {O}_{at \%} + 3 {N}_{at \%}} \qquad [ Equation 2 ]$$
In Equation 2, N_{at %} means the elemental content of nitrogen atoms with respect to the aluminum oxynitride, Al_{at %} means the elemental content of aluminum atoms with respect to the aluminum oxynitride, and O_{at %} means the elemental content of oxygen atoms with respect to the aluminum oxynitride.

4. The conductive structure body of claim 1, wherein a thickness of the second light reflection reducing layer is 5 nm or more and 60 nm or less.

5. The conductive structure body of claim 1, wherein a thickness of the first light reflection reducing layer is 10 nm or more and 100 nm or less.

6. The conductive structure body of claim 1, wherein a specific resistance of the second light reflection reducing layer is 10⁻⁴ Ωcm or more and 5×10⁻³ Ωcm or less.

7. The conductive structure body of claim 1, wherein a total reflection of the conductive structure body is 40% or less.

8. The conductive structure body of claim 1, wherein an extinction coefficient k of the conductive line is 1.2 or more and 2.2 or less in light having a wavelength of 633 nm.

9. The conductive structure body of claim 1, wherein a refractive index n of the conductive line is 2 or more and 2.4 or less in the light having a wavelength of 600 nm.

10. The conductive structure body of claim 1, further comprising:
a flexible printed circuit board (FPCB) on the conductive line configuring the pad portion.

11. The conductive structure body of claim 10, further comprising:
an anisotropic conductive film (ACF) between the conductive line configuring the pad portion and the FPCB.

12. The conductive structure body of claim 1, wherein the screen portion includes a plurality of apertures and a conductive pattern including the conductive line partitioning the apertures.

13. The conductive structure body of claim 12, wherein a line width of the conductive line configuring the screen portion is 0.1 μm or more and 100 μm or less.

14. The conductive structure body of claim 12, wherein a line gap between adjacent conductive lines in the conductive line configuring the screen portion is 0.1 μm or more and 100 μm or less.

15. The conductive structure body of claim 1, wherein the thickness of the metal layer is 10 nm or more and 1 μm or less.

16. A manufacturing method of the conductive structure body of claim 1, the manufacturing method comprising:
preparing a substrate;
forming a metal layer on the substrate;
forming a first light reflection reducing layer on the metal layer;
forming a second light reflection reducing layer on the first light reflection reducing layer; and
patterning of forming a conductive line configuring a screen portion, a wiring portion, and a pad portion by patterning the metal layer, the first light reflection reducing layer, and the second light reflection reducing layer.

17. The manufacturing method of claim 16, wherein in the patterning, the metal layer, the first light reflection reducing layer, and the second light reflection reducing layer are simultaneously patterned.

18. A touch panel including the conductive structure body of claim 1.

19. A display device including the touch panel of claim 18.
